(19) United States
(12) Patent Application Publication
(10) Pub. No.: US 2017/0243698 A1
(43) Pub. Date: Aug. 24, 2017

(54) PHOTOELECTRIC CONVERSION ELEMENT

(71) Applicants: Naomichi KANEI, Shizuoka (JP); Yuuji TANAKA, Shizuoka (JP); Ryota ARAI, Shizuoka (JP); Tsuyoshi MATSUYAMA, Shizuoka (JP); Tokushige KINO, Shizuoka (JP)

(72) Inventors: Naomichi KANEI, Shizuoka (JP); Yuuji TANAKA, Shizuoka (JP); Ryota ARAI, Shizuoka (JP); Tsuyoshi MATSUYAMA, Shizuoka (JP); Tokushige KINO, Shizuoka (JP)

(73) Assignee: RICOH COMPANY, LTD., Tokyo (JP)

(21) Appl. No.: 15/438,262

(22) Filed: Feb. 21, 2017

(30) Foreign Application Priority Data
Feb. 22, 2016 (JP) 2016-031377

(51) Int. Cl. H01G 9/20; H01L 51/44

(52) U.S. Cl. CPC H01G 9/2009; H01L 51/441; H01L 51/448; H01G 9/2059; H01L 51/0072

(57) ABSTRACT

A photoelectric conversion element including a first substrate, a first electrode on the first substrate, a photoelectric conversion layer on the first electrode, a second electrode on the photoelectric conversion layer, a second substrate on the second electrode, and a sealing member disposed between the first electrode and the second substrate and configured to seal at least the photoelectric conversion layer, the first electrode including a through section, the sealing member being in contact with the first substrate through the through section.

### CROSS-REFERENCE TO RELATED APPLICATIONS

The present application claims priority under 35 U.S.C. §119 to Japanese Patent Application No. 2016-031377, filed Feb. 22, 2016. The contents of which are incorporated herein by reference in their entirety.

### BACKGROUND OF THE INVENTION

Field of the Invention

The present disclosure relates to a photoelectric conversion element.

Description of the Related Art

In recent years, driving power for electronic circuits has been significantly reduced, and it has become possible to drive various electronic parts such as sensors with a weak power (of a μW order). Expected uses of sensors include application to energy harvesting elements as stand-alone power systems capable of generating power instantly. Among such energy harvesting elements, solar cells (which are a kind of photoelectric conversion elements) are drawing attention.

Among the solar cells, solid dye-sensitized solar cells has been known that a value of electric current is significantly reduced by water vapor present outside is penetrated inside the cells. Accordingly, a sealing technique is important in order not to allow water vapor present outside to penetrate inside a cell. Similarly, organic EL elements have been also known that coloring is caused in a non-colored region (so-called a dark spot) due to water vapor present outside, and eventually the entire organic EL element becomes uncolored.

Accordingly, proposed is, for example, that a convex-concave region is disposed at a periphery of a substrate, on which a light-emitting element has been formed, a connection electrode formed of a conductive paste is formed on the convex-concave region, and sealing is performed using a sealing member via the convex-concave region and the conductive paste, in order not to allow water vapor present outside to penetrate inside the cell (see Japanese Unexamined Patent Application Publication No. 2010-198821).

### SUMMARY OF THE INVENTION

According to one aspect of the present disclosure, a photoelectric conversion element includes a first substrate, a first electrode on the first substrate, a photoelectric conversion layer on the first electrode, a second electrode on the photoelectric conversion layer, a second substrate on the second electrode, and a sealing member disposed between the first electrode and the second substrate and configured to seal at least the photoelectric conversion layer. The first electrode includes a through section, and the sealing member is in contact with the first substrate through the through section.

### BRIEF DESCRIPTION OF THE DRAWINGS

FIG. 1A is a schematic cross-sectional view illustrating one example of the photoelectric conversion element of the present disclosure;

FIG. 1B is a schematic cross-sectional view illustrating another example of the photoelectric conversion element of the present disclosure;

FIG. 1C is a schematic cross-sectional view illustrating yet another example of the photoelectric conversion element of the present disclosure;

FIG. 2A is a schematic top view illustrating a position of a through section of a first electrode in the photoelectric conversion element illustrated in FIGS. 1A and 1B;

FIG. 2B is a schematic top view illustrating a position of a through section of a hole-blocking layer of the photoelectric conversion element illustrated in FIG. 1C;

FIG. 2C is a schematic top view illustrating a position of a sealing member of the photoelectric conversion element illustrated in FIGS. 1A to 1C;

FIG. 3A is an enlarged top view illustrating one example of a through section in the photoelectric conversion element of the present disclosure;

FIG. 3B is an enlarged top view illustrating another example of a through section in the photoelectric conversion element of the present disclosure;

FIG. 3C is an enlarged top view illustrating yet another example of a through section in the photoelectric conversion element of the present disclosure;

FIG. 3D is an enlarged top view illustrating yet another example of a through section in the photoelectric conversion element of the present disclosure;

FIG. 4A is a schematic top view illustrating a through section in the photoelectric conversion element of Example 1;

FIG. 4B is a schematic top view illustrating a state after disposing a sealing member to the through section in the photoelectric conversion element of Example 1;

FIG. 5 is an enlarged top view illustrating the through section in the photoelectric conversion element of Example 1;

FIG. 6A is a schematic top view illustrating a through section in the photoelectric conversion element of Example 2;

FIG. 6B is a schematic top view illustrating a state after disposing a sealing member to the through section in the photoelectric conversion element of Example 2;

FIG. 7 is an enlarged top view illustrating the through section in the photoelectric conversion element of Example 2;

FIG. 8A is a schematic top view illustrating a through section in the photoelectric conversion element of Example 3;

FIG. 8B is a schematic top view illustrating a state after disposing a sealing member to the through section in the photoelectric conversion element of Example 3;

FIG. 9 is an enlarged top view illustrating the through section in the photoelectric conversion element of Example 3;

FIG. 10A is a schematic top view illustrating a through section in the photoelectric conversion element of Example 4;

FIG. 10B is a schematic top view illustrating a state after disposing a sealing member to the through section in the photoelectric conversion element of Example 4;

FIG. 11 is an enlarged top view illustrating the through section in the photoelectric conversion element of Example 4;

FIG. 12A is a schematic top view illustrating a through section in the photoelectric conversion element of Example 5;

FIG. 12B is a schematic top view illustrating a state after disposing a sealing member to the through section in the photoelectric conversion element of Example 5;

FIG. 13 is an enlarged top view illustrating the through section in the photoelectric conversion element of Example 5;

FIG. 14A is a schematic top view illustrating a through section in the photoelectric conversion element of Example 6;

FIG. 14B is a schematic top view illustrating a state after disposing a sealing member to the through section in the photoelectric conversion element of Example 6;

FIG. 15 is an enlarged top view illustrating the through section in the photoelectric conversion element of Example 6;

FIG. 16A is a schematic top view illustrating a through section in the photoelectric conversion element of Comparative Example 1;

FIG. 16B is a schematic top view illustrating a state after disposing a sealing member to the through section in the photoelectric conversion element of Comparative Example 1;

FIG. 17A is a schematic top view illustrating a hole section in the photoelectric conversion element of Comparative Example 2;

FIG. 17B is a schematic top view illustrating a state after disposing a sealing member to the hole section of the photoelectric conversion element of Comparative Example 2;

FIG. 18A is a schematic top view illustrating a through section in the photoelectric conversion element of Comparative Example 3;

FIG. 18B is a schematic top view illustrating a state after applying a silver paste to the through section of the photoelectric conversion element of Comparative Example 3;

FIG. 18C is a schematic top view illustrating a state after disposing a sealing member after the application of the silver paste to the photoelectric conversion element of Comparative Example 3;

FIG. 19 is an enlarged top view illustrating the through section of the photoelectric conversion element of Comparative Example 3;

FIG. 20A is a schematic top view illustrating the photoelectric conversion element of Comparative Example 4; and

FIG. 20B is a schematic top view illustrating a state after disposing a sealing member to the photoelectric conversion element of Comparative Example 4.

### DESCRIPTION OF THE EMBODIMENTS

### (Photoelectric Conversion Element)

A photoelectric conversion element of the present disclosure includes a first substrate, a first electrode on the first substrate, a photoelectric conversion layer on the first electrode, a second electrode on the photoelectric conversion layer, a second substrate on the second electrode, and a sealing member disposed between the first electrode and the second substrate and configured to seal at least the photoelectric conversion layer. The first electrode includes a through section, and the sealing member is in contact with the first substrate through the through section.

In the photoelectric conversion element of the present disclosure, the hole-blocking layer is preferably disposed between the first electrode and the sealing member, the hole-blocking layer preferably includes a through section connected to the through section of the first electrode, and the sealing member is preferably in contact with the first substrate through the through section of the hole-blocking layer and the through section of the first electrode.

The photoelectric conversion element of the present disclosure has accomplished based on the following finding. In a known sealing technique in the art, a reduction in a photoelectric conversion efficiency in high-temperature and high-humidity environments cannot be suppressed only by sealing an irregular region disposed at a periphery of a substrate with a sealing material via a conductive paste, and a satisfactory product cannot be obtained.

The present disclosure has an object to provide a photoelectric conversion element, which can suppress a reduction in a photoelectric conversion efficiency even in high-temperature and high-humidity environments. Note that, the high-temperature and high-humidity environment means that a temperature is 40° C. or higher but 90° C. or lower and a relative humidity is 80% or higher but 95% or lower.

The present disclosure can provide a photoelectric conversion element, which can suppress a reduction in a photoelectric conversion efficiency even in high-temperature and high-humidity environments.

### <First Substrate>

The first substrate is not particularly limited, and substrates known in the art can be used as the first substrate. The first substrate is preferably a transparent material. Examples of the first substrate include glass, transparent plastic plates, transparent plastic films, and inorganic transparent crystals.

### <First Electrode>

The first electrode is not particularly limited and may be appropriately selected depending on the intended purpose, as long as the first electrode is formed of a conductive material transparent to visible light, and the first electrode has the through section. For example, known electrodes used for typical photoelectric conversion elements or liquid crystal panels can be used as the first electrode.

Examples of a material of the first electrode include tin-doped indium oxide (may be referred to as “ITO” hereinafter), fluorine-dope tin oxide (may be referred to as “FTO” hereinafter), antimony-doped tin oxide (may be referred to as “ATO” hereinafter), indium zinc oxide, niobium titanium oxide, and graphene. The above-listed materials may be used alone, or two or more of the above-listed materials may be used in combination as a laminate.

An average thickness of the first electrode is not particularly limited and may be appropriately selected depending on the intended purpose. The average thickness is preferably 5 nm or greater but 100 μm or less, and more preferably 50 nm or greater but 10 μm or less.

Since the first electrode is in the form of a film, the first electrode is preferably disposed on the first substrate including a material transparent to visible light. It is also possible to use a known integrated body of the first electrode and the first substrate. Examples of the integrated body include FTO-coated glass, ITO-coated glass, zinc oxide/aluminium-coated glass, FTO-coated transparent plastic film, and ITO-coated transparent plastic film. Moreover, another example of a known integrated body of the first electrode and the first substrate is an integrated body, in which a transparent electrode formed of tin oxide or indium oxide doped with a cation or an anion different in valence or a metal electrode formed into a light-transmissive structure such as a mesh form and a stripe form is disposed on a substrate such as a glass substrate.

The above-listed examples may be used alone, or two or more of the above-listed examples may be used in combination as a mixture or a laminate. Moreover, a metal lead line may be used in combination for the purpose of lowering an electric resistance value

Examples of a material of the metal lead line includes metals, such as aluminium, copper, silver, gold, platinum, and nickel. The metal lead line can be formed by a method including disposing a metal lead line on a substrate by vapor deposition, sputtering, or bonding, and disposing ITO or FTO onto the metal lead wire.

### <<Through Section>>

The through section is not particularly limited and may be appropriately selected depending on the intended purpose, as long as the through section is disposed in a manner that the sealing member is in contact with the first substrate through the through section. The through section preferably includes a plurality of through holes, and the through holes are preferably formed in at least a region of the first electrode that is joined with the sealing member.

The through section preferably includes through holes disposed in a dot pattern with even gaps. To dispose the through holes with even gaps means that each of A and B has a constant length, and A and B are disposed periodically, where A is a minimum opening length of the through hole and B is a minimum distance between the through holes adjacent to each other.

The through section may be connected to a through section of the hole-blocking layer disposed on the first electrode. Note that, an area of the first electrode to be joined with the sealing member may be hollowed in the shape of a concave.

### —Through Holes—

The through holes are not particularly limited and may be appropriately selected depending on the intended purpose, as long as the through holes go through the first electrode.

An opening shape of each of the through holes is not particularly limited and may be appropriately selected depending on the intended purpose. Examples of the opening shape include a line shape, a tapered shape, and a circular shape. Among the above-listed examples, a circular shape is preferable. When an opening shape of each through hole is a circular shape, the sealing member is easily brought into contact with the first substrate through the through section, and a contact area of the first electrode and the first substrate with the sealing member becomes large. Therefore, such a shape is preferable because adhesion is enhanced.

In the case where electrode drawing parts (terminals) are disposed in a plurality of direction, for example, the electrode drawing parts (terminals) may be electrically insulated when the through holes are formed by sweeping laser in one direction, if an opening shape of the through hole is a line shape. Accordingly, the opening shape of the through hole is preferably a circular shape.

In the case where the through holes are disposed in a dot pattern with even gaps, the following formula A>B is preferably satisfied. When the following formula A>B is satisfied, the density of the through holes is high, and a contact area between the first electrode and the first substrate with the sealing member is large. Therefore, adhesion between the first electrode and the first substrate with the sealing member is enhanced, and a sealing effect can be sufficiently exhibited. Accordingly, it is advantageous when the formula A>B is satisfied.

The minimum opening length A of the through hole is not particularly limited and may be appropriately selected depending on the intended purpose. The minimum opening length A is preferably 5 μm or greater but 500 μm or less. It is advantageous when the minimum opening length A is within the above-described preferable range because the density of the through holes becomes high and a contact area with the sealing member is large, and therefore a sealing effect can be sufficiently exhibited.

The minimum distance B between the through holes adjacent to each other is not particularly limited and may be appropriately selected depending on the intended purpose. The minimum distance B is preferably 1 μm or greater but 400 μm or less. It is advantageous when the minimum distance B is within the above-described preferable range because, as well as having sufficient conductivity, the density of the through hole becomes high and a contact area between the first electrode and the first substrate with the sealing member is large, and therefore a sealing effect can be sufficiently exhibited.

A formation method of the through section is not particularly limited, and the through section can be formed according to any methods known in the art. Examples of the formation method include sand blasting, water blasting, using sand paper, chemical etching, and laser processing. Among the above-listed examples, laser processing is preferable because fine through holes are easily formed by predetermined patterning.

### <Photoelectric Conversion Layer>

The photoelectric conversion layer is not particularly limited and may be appropriately selected depending on the intended purpose. The photoelectric conversion layer preferably includes an electron-transport layer and a hole-transport layer.

### <<Electron-Transport Layer>>

The electron-transport layer is disposed on the first electrode. The electron-transport layer is typically formed as a porous layer, and includes an electron-transport material, such as semiconductor particles.

Moreover, the electron-transport layer may be a single layer or a multilayer. In the case where the electron-transport layer is a multilayer, a multilayer of dispersion liquids of semiconductor particles may be applied where each layer includes semiconductor particles of a different particle diameter. Alternatively, a multilayer of coated layers each having different types of a semiconductor, or different compositions of a resin or additives may be applied. The multilayer coating is an effective method when an average thickness is insufficient with one coating.

### —Electron-Transport Material—

The electron-transport material is not particularly limited and may be appropriately selected depending on the intended purpose. Examples of the electron-transport material include semiconductor materials in the form of particles, rods, and tubes. Among the above-listed examples, granular semiconductor particles are preferable, and the semiconductor particles, on which a below-mentioned photosensitizing compound is adsorbed is more preferable.

The semiconductor particles are not particularly limited, and semiconductor particles known in the art can be used as the semiconductor particles. Examples of the semiconductor particles include single semiconductors, compound semiconductors, and compounds having the Perovskite structure.

Examples of the single semiconductors include silicon and germanium.

Examples of the compound semiconductor include: chalcogenides of metals; phosphides of zinc, gallium, indium, or cadmium; gallium arsenide; copper-indium-selenide; and copper-indium-sulfide.

Examples of the chalcogenides of metals include: oxides of titanium, tin, zinc, iron, tungsten, zirconium, hafnium, strontium, indium, cerium, yttrium, lanthanum, vanadium, niobium, or tantalum; sulfides of cadmium, zinc, lead, silver, antimony, or bismuth; selenides of cadmium or lead; and telluride of cadmium

Examples of the compounds having the Perovskite structure include strontium titanate, calcium titanate, sodium titanate, barium titanate, and potassium niobate.

The above-listed examples may be used alone or in combination.

Among the above-listed examples, oxide semiconductors are preferable, and at least one selected from the group consisting of titanium oxide, zinc oxide, tin oxide, and niobium oxide is more preferable.

A crystal type of the semiconductor particles is not particularly limited and may be appropriately selected depending on the intended purpose. The semiconductor particles may be monocrystalline, polycrystalline, or amorphous.

A number average particle diameter of primary particles of the semiconductor particles is not particularly limited and may be appropriately selected depending on the intended purpose. The number average particle diameter of the primary particles is preferably 1 nm or greater but 100 nm or less, and more preferably 5 nm or greater but 50 nm or less. Moreover, an efficiency may be improved with an effect of scattering incident light by mixing or laminating semiconductor particles having a number average particle diameter larger than the above-mentioned number average particle diameter. In this case, the number average particle diameter is preferably 50 nm or greater but 500 nm or less.

An average thickness of the electron-transport layer is not particularly limited and may be appropriately selected depending on the intended purpose. The average thickness is preferably 100 nm or greater but 100 μm or less, more preferably 100 nm or greater but 50 μm or less, and even more preferably 100 nm or greater but 10 μm or less. When the average thickness of the electron-transport layer is within the above-mentioned preferable range, an amount of the photosensitizing compound born per unit projected area is appropriate, a capturing rate of light is high, a diffusion length of injected electrons is hardly increased, and a loss due to charge recombination can be minimized. Accordingly, such the average thickness is advantageous.

A production method of the electron-transport layer is not particularly limited and may be appropriately selected depending on the intended purpose. Examples of the production method include: a method where a thin film is formed in vacuum, such as sputtering; and wet film-forming methods. Among the above-listed examples, the wet film-forming methods are preferable in view of a production cost. More preferable is a method where a paste, in which a powder or sol of the semiconductor particles is dispersed, is prepared, and the paste is applied onto the first electrode serving as an electron-collector electrode substrate, or the first electrode.

The wet film-forming methods are not particularly limited and may be selected from methods known in the art. Examples of the wet film-forming methods include dipping, spraying, wire-bar coating, spin coating, roller coating, blade coating, and gravure coating. As a wet printing method, moreover, various methods, such as letterpress, offset, gravure, intaglio, rubber plate, and screen printing, can be used.

In the case where a dispersion liquid of the semiconductor particles is produced by mechanical pulverization using a mill, the dispersion liquid is formed by dispersing at least semiconductor particles alone or a mixture of semiconductor particles and a resin, in water or a solvent.

Examples of the resin include: polymers or copolymers of vinyl compounds, such as styrene, vinyl acetate, acrylic ester, and methacrylic ester; silicone resins; phenoxy resins; polysulfone resins; polyvinyl butyral resins; polyvinyl formal resins; polyester resins; cellulose ester resins; cellulose ether resins; urethane resins; phenol resins; epoxy resins; polycarbonate resins; polyallylate resins; polyamide resins; and polyimide resins. The above-listed examples may be used alone or in combination.

Examples of the solvent include water, alcohol solvents, ketone solvents, ester solvents, ether solvents, amide solvents, halogenated hydrocarbon solvents, and hydrocarbon solvents.

Examples of the alcohol solvents include methanol, ethanol, isopropyl alcohol, and α-terpineol.

Examples of the ketone solvents include acetone, methyl ethyl ketone, and methyl isobutyl ketone.

Examples of the ester solvents include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvents include dichloromethane, chloroform, bromoform, methyl iodine, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvents include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

The above-listed examples may be used alone or in combination.

An acid, a surfactant, or a chelating agent may be added to the dispersion liquid of the semiconductor particles, or a paste of the semiconductor particles obtained by a sol-gel method in order to prevent reaggregation of particles.

Examples of the acid include hydrochloric acid, nitric acid, and acetic acid.

Examples of the surfactant include polyoxyethylene octyl phenyl ether.

Examples of the chelating agent include acetylacetone, 2-aminoethanol, and ethylenediamine.

Moreover, it is also effective to add a thickening agent for improving film-formability.

Examples of the thickening agent include polyethylene glycol, polyvinyl alcohol, and ethyl cellulose.

After a dispersion liquid or paste of the semiconductor particles is applied, the semiconductor particles are electrically brought into contact with each other and preferably subjected to a treatment, such as firing, microwave irradiation, electron beam irradiation, or laser light irradiation, in order to improve a film strength or adhesion to a substrate. The above-listed treatment may be performed alone or in combination.

In the case where a dispersion liquid or paste of the semiconductor particles is fired, a firing temperature is not particularly limited and may be appropriately selected depending on the intended purpose. When the temperature is too high, however, resistance with a substrate becomes high, or the semiconductor particles may be melted. Therefore, the firing temperature is preferably 30° C. or higher but 700° C. or lower, and more preferably 100° C. or higher but 600° C. or lower. Moreover, a firing duration is not particularly limited and may be appropriately selected depending on the intended purpose. The firing duration is preferably 10 minutes or longer but 10 hours or shorter.

In the case where microwave irradiation is performed on the semiconductor particles, microwaves may be applied from a side of a surface to which the electron-transport layer, or from a side of a surface to which the electron-transport layer is not formed. An irradiation duration is not particularly limited and may be appropriately selected depending on the intended purpose. The irradiation duration is preferably 1 hour or shorter.

After firing the semiconductor particles, for example, chemical plating using a mixed solution of an aqueous solution of titanium tetrachloride and an organic solvent, or electrochemical plating using a titanium trichloride aqueous solution may be performed for the purpose of increasing surface areas of the semiconductor particles, or enhancing an electron-injection efficiency from the below-mentioned photosensitizing compound to the semiconductor particles.

A porous state is formed in the film obtained by depositing the semiconductor particles having a diameter of several tens of nanometers by, for example, firing. This nanoporous structure has an extremely large surface area. The surface area can be expressed by a roughness factor.

The roughness factor is a value representing an actual area inside the pores relative to an area of the semiconductor particles coated on the first substrate. Accordingly, the greater roughness factor is more preferable, but the roughness factor is preferably 20 or greater in view of a relationship with an average thickness of the electron-transport layer.

### —Photosensitizing Compound—

In order to improve the photoelectric conversion efficiency further, the photosensitizing compound may be adsorbed on surfaces of the semiconductor particles.

The photosensitizing compound is not particularly limited as long as the photosensitizing compound is a compound that is optically excited by excitation liquid for use. Known photosensitizing compounds can be used as the photosensitizing compound. Specifically, examples of the photosensitizing compound include: metal complex compounds disclosed in Japanese Translation of PCT International Application Publication No. JP-T-07-500630 and Japanese Unexamined Patent Application Publication Nos. 10-233238, 2000-26487, 2000-323191, and 2001-59062; coumarin compounds disclosed in Japanese Unexamined Patent Application Publication Nos. 10-93118, 2002-164089, and 2004-95450, and J. Phys. Chem. C, 7224, Vol. 111 (2007); polyene compounds disclosed in Japanese Unexamined Patent Application Publication No. 2004-95450 and Chem. Commun., 4887 (2007); indoline compounds disclosed in Japanese Unexamined Patent Application Publication Nos. 2003-264010, 2004-63274, 2004-115636, 2004-200068, and 2004-235052, and J. Am. Chem. Soc., 12218, Vol. 126 (2004), Chem. Commun., 3036 (2003), and Angew. Chem. Int. Ed., 1923, Vol. 47 (2008); thiophene compounds disclosed in J. Am. Chem. Soc., 16701, Vol. 128 (2006), and J. Am. Chem. Soc., 14256, Vol. 128 (2006); cyanine dyes disclosed in Japanese Unexamined Patent Application Publication Nos. 11-86916, 11-214730, 2000-106224, 2001-76773, and 2003-7359; merocyanine dyes disclosed in Japanese Unexamined Patent Application Publication Nos. 11-214731, 11-238905, 2001-52766, 2001-76775, and 2003-7360; 9-aryl-xanthene compounds disclosed in Japanese Unexamined Patent Application Publication Nos. 10-92477, 11-273754, 11-273755, and 2003-31273; triaryl methane compounds disclosed in Japanese Unexamined Patent Application Publication Nos. 10-93118 and 2003-31273; phthalocyanine compounds disclosed in Japanese Unexamined Patent Application Publication Nos. 09-199744, 10-233238, 11-204821, and 11-265738, J. Phys. Chem., 2342, Vol. 91 (1987), J. Phys. Chem. B, 6272, Vol. 97 (1993), Electroanal. Chem., 31, Vol. 537 (2002), Japanese Unexamined Patent Application Publication No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008); and porphyrin compounds. Among the above-listed examples, metal complex compounds, coumarin compounds, polyene compounds, indoline compounds, and thiophene compounds are preferable, and D131 represented by Structural Formula (1) below, D102 represented by Structural Formula (2) below, and D358 represented by Structural Formula (3), all of which are available from MITSUBISHI PAPER MILLS LIMITED, are more preferable.

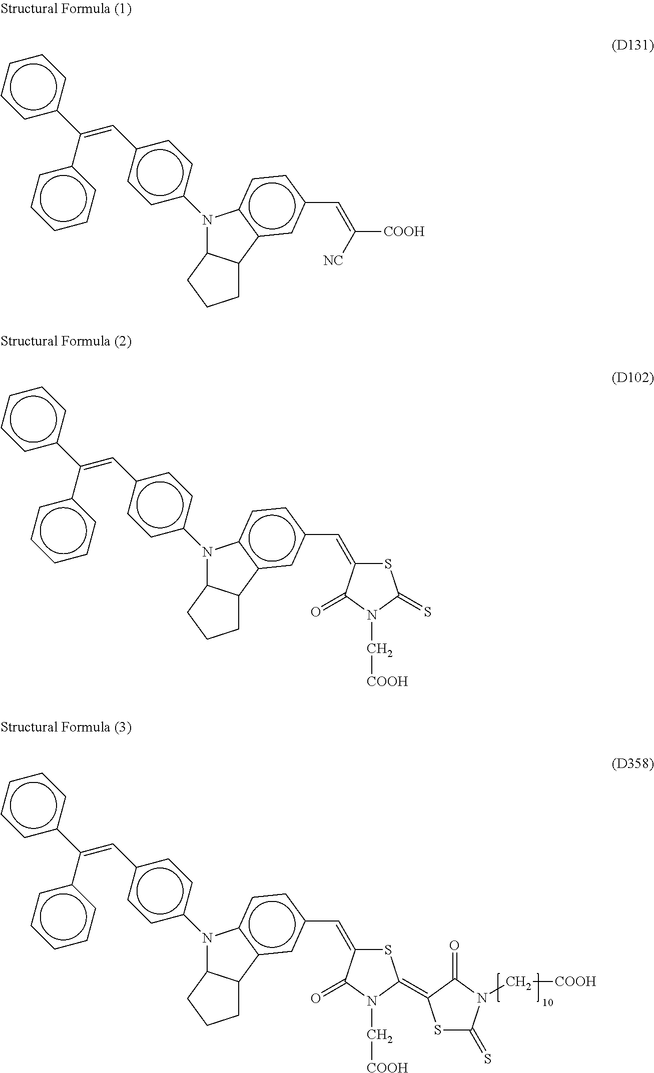

Examples of a method for adsorbing the photosensitizing compound to the semiconductor particles serving as the electron-transport material include: a method where an electron-collector electrode including the semiconductor particles is immersed in the photosensitizing compound solution or the photosensitizing compound dispersion liquid; and a method where the photosensitizing compound solution or the photosensitizing compound dispersion liquid is applied onto the electron-transport layer to adsorb the photosensitizing compound onto the electron-transport layer.

In case of the method where an electron-collector electrode including the semiconductor particles is immersed in the photosensitizing compound solution or the photosensitizing compound dispersion liquid, immersing, an immersing method, a dipping method, a roller method, and an air knife method may be used.

In case of the method where the photosensitizing compound solution or the photosensitizing compound dispersion liquid is applied onto the electron-transport layer to adsorb the photosensitizing compound onto the electron-transport layer, a wire bar method, a slide hopper method, an extrusion method, a curtain method, a spinning method, and a spraying method may be used.

The photosensitizing compound may be adsorbed under a supercritical fluid using, for example, carbon dioxide.

When the photosensitizing compound is made adsorbed on the semiconductor particles, a condensing agent may be used in combination.

The condensing agent may be a substance that exhibits a catalytic function to physically or chemically bond the photosensitizing compound onto surfaces of the semiconductor particles, or a substance that acts stoichiometrically to cause a chemical equilibrium to move in an advantageous manner.

Moreover, thiol or a hydroxyl compound may be added as a condensing aid.

Examples of a solvent, in which the photosensitizing compound is dissolved or dispersed, include water, alcohol solvents, ketone solvents, ester solvents, ether solvents, amide solvents, halogenated hydrocarbon solvents, and hydrocarbon solvents.

Examples of the alcohol solvents include methanol, ethanol, and isopropyl alcohol.

Examples of the ketone solvent include acetone, methyl ethyl ketone, and methyl isobutyl ketone.

Examples of the ester solvents include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvents include dichloromethane, chloroform, bromoform, methyl iodine, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvents include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

The above-listed examples may be used alone or in combination.

The photosensitizing compound may be used in combination with a disaggregating agent because some of the photosensitizing compounds works more efficiently if aggregations between compounds are prevented, depending on the photosensitizing compound for use.

The disaggregating agent is not particularly limited, and may be appropriately selected depending on a dye for use. The disaggregating agent is preferably a steroid compound such as cholic acid and chenodeoxycholic acid, long-chain alkylcarboxylic acid, or long-chain alkylphosphonic acid.

An amount of the disaggregating agent is preferably 0.01 parts by mass or greater but 500 parts by mass or less, and more preferably 0.1 parts by mass or greater but 100 parts by mass or less, relative to 1 part by mass of the photosensitizing compound.

A temperature at which the photosensitizing compound alone, or a combination of the photosensitizing compound and the disaggregating agent is adsorbed on the semiconductor particles is preferably −50° C. or higher but 200° C. or lower.

A duration for the adsorption is preferably 5 seconds or longer but 1,000 hours or shorter, more preferably 10 seconds or longer but 500 hours or shorter, and even more preferably 1 minute or longer but 150 hours or shorter.

The adsorption is preferably performed in the dark. Moreover, the adsorption may be performed in a still state or under stirring.

The stirring is not particularly limited and may be appropriately selected depending on the intended purpose. Examples of a method of the stirring include methods using a stirrer, a ball mill, a paint conditioner, a sand mill, an attritor, a disperser, and ultrasonic dispersion.

### <<Hole-Transport Layer>>

Examples of a material of the hole-transport layer include electrolytic solutions each obtained by dissolving a redox couple in an organic solvent, gel electrolytes each obtained by impregnating a polymer matrix with a liquid obtained by dissolving a redox couple in an organic solvent, molten salts each including a redox couple, solid electrolytes, inorganic hole-transport materials, and organic hole-transport materials. Among the above-listed examples, organic hole-transport materials are preferable.

Note that, there are descriptions below using the organic hole-transport material as an example, but the material of the hole-transport layer is not limited to the organic hole-transport material.

The hole-transport layer may have a single layer structure formed of a single material, or a laminate structure including a plurality of compounds. In the case where the hole-transport layer has a laminate structure, a polymer material is preferably used for an area of the hole-transport layer close to the second electrode. Use of a polymer material having excellent film formability can level a surface of a porous electron-transport layer, and photoelectric conversion characteristic can be improved. Therefore, use of the polymer material is advantageous.

Since the polymer material is unlikely to penetrate into the porous electron-transport layer, moreover, the polymer material has excellent coatability over a surface of the porous electron-transport layer, and gives an effect of preventing short-circuits when an electrode is provided. Accordingly, a higher performance can be obtained.

As an organic hole-transport material used for the hole-transport layer having a single layer structure, any of organic hole-transport compounds known in the art can be used.

Specific examples of the known organic hole-transport compounds include oxadiazole compounds disclosed in, for example, Japanese Examined Patent Publication No. 34-5466, triphenylmethane compounds disclosed in, for example, Japanese Examined Patent Publication No. 45-555, pyrazoline compounds disclosed in, for example, Japanese Examined Patent Publication No. 52-4188, hydrazine compounds disclosed in, for example, Japanese Examined Patent Publication No. 55-42380, oxadiazole compounds disclosed in, for example, Japanese Unexamined Patent Application Publication No. 56-123544, tetraarylbenzidine compounds disclosed in Japanese Unexamined Patent Application Publication No. 54-58445, and stilbene compounds disclosed in Japanese Unexamined Patent Application Publication No. 58-65440 or Japanese Unexamined Patent Application Publication No. 60-98437.

Among the above-listed examples, a hole-transport material (2,2′,7,7′-tetrakis(N,N-di-p-methoxyphenylamino)-9,9′-spirobifluorene: spiro-OMeTAD) disclosed in Adv. Mater., 813, vol. 17, (2005) is particularly preferable.

The spiro-OMeTAD has a high Hall mobility and includes two benzidine skeleton molecules that are bound with each other in a twisted state. Hence, the spiro-OMeTAD forms an electron cloud close to a spherical shape and has a good hopping conductivity between the molecules, leading to a more excellent photoelectric conversion characteristic. The spiro-OMeTAD also has a high solubility, is soluble in various organic solvents, and is amorphous (i.e., an amorphous substance having no crystalline structure). Therefore, the spiro-OMeTAD is likely to be densely filled in the porous electron-transport layer and has properties useful for a solid dye-sensitized solar cell. Moreover, the spiro-OMeTAD does not have a light absorbing property at 450 nm or greater. Therefore, the spiro-OMeTAD can enable light to be efficiently absorbed into the photosensitizing compound, and has a property useful for a solid dye-sensitized solar cell.

The hole-transport layer formed of the spiro-OMeTAD is not particularly limited and may be appropriately selected depending on the intended purpose. It is however preferable that the hole-transport layer has a structure where the hole-transport layer is penetrated into voids of the porous electron-transport layer.

Moreover, an average thickness of the hole-transport layer formed of the spiro-OMeTAD is not particularly limited and may be appropriately selected depending on the intended purpose. The average thickness of the hole-transport layer formed of the spiro-OMeTAD is preferably 0.01 μm or greater on the electron-transport layer, and more preferably 0.1 μm or greater but 10 μm or less.

As a polymer material used for the hole-transport layer having a laminate structure and disposed at a position close to the second electrode, any of hole-transport polymer materials known in the art can be used.

Examples of the known hole-transport polymer materials include polythiophene compounds, polyphenylenevinylene compounds, polyfluorene compounds, polyphenylene compounds, polyarylamine compounds, and polythiadiazole compounds.

Examples of the polythiophene compound include poly(3-n-hexylthiophene), poly(3-n-octyloxythiophene), poly(9,9′-dioctyl-fluorene-co-bithiophene), poly(3,3′″-didodecyl-quarter thiophene), poly(3,6-dioctylthieno[3,2-b]thiophene), poly(2, 5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene).

Examples of the polyphenylenevinylene compounds include poly[2-methoxy-5-(2-ethylhexyloxy)-1,4-phenylenevinylene], poly[2-methoxy-5-(3,7-dimethyloctyloxy)-1,4-phenylenevinylene], and poly[(2-methoxy-5-(2-ethylphexyloxy)-1,4-phenylenevinylene)-co-(4,4′-biphenylene-vinylene)].

Examples of the polyfluorene compounds include poly(9,9′-didodecylfluorenyl-2, 7-diyl), poly[(9,9-dioctyl-2, 7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)].

Examples of the polyphenylene compounds include poly[2,5-dioctyloxy-1,4-phenylene], and poly[2,5-di(2-ethylhexyloxy-1,4-phenylene].

Examples of the polyarylamine compounds include poly[(9,9-dioctylfluorenyl-2, 7-diyl)-alt-co-(N, N′-diphenyl)-N, N′-di(p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N, N′-bis(4-octyloxyphenyl)benzidine-N,N′-(1,4-diphenylene)], poly[(N,N′-bis(4-(2-ethylhexyloxy)phenyl)benzidine-N,N-(1,4-diphenylene)], poly[phenylimino-1,4-phenylenevinylene-2,5-dioctyloxy-1, 4-phenylenevinylene-1, 4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene].

Examples of the polythiadiazole compounds include poly[(9,9-dioctylfluorenyl-2, 7-diyl)-alt-co-(1,4-benzo(2,1′,3)thiadiazole] and poly(3, 4-didecylthiophene-co-(1,4-benzo(2,1′,3)thiadiazole).

Among the above-listed examples, the polythiophene compounds and the polyarylamine compounds are preferable in view of carrier mobility and ionization potential.

Moreover, various additives may be added to the organic hole-transport material.

Examples of the additive include iodine, metal iodides, quaternary ammonium salts, metal bromides, bromine salts of quaternary ammonium compounds, metal chlorides, metal acetates, metal sulfates, metal complexes, sulfur compounds, ionic liquids disclosed in Inorg. Chem. 35 (1996) 1168, lithium compounds, and basic compounds.

Examples of the metal iodides include lithium iodide, sodium iodide, potassium iodide, cesium iodide, calcium iodide, copper iodide, iron iodide, and silver iodide.

Examples of the quaternary ammonium salts include tetraalkylammonium iodide and pyridinium iodide.

Examples of the metal bromides include lithium bromide, sodium bromide, potassium bromide, cesium bromide, and calcium bromide.

Examples of the bromine salts of quaternary ammonium compounds include tetraalkylammonium bromide and pyridinium bromide.

Examples of the metal chlorides include copper chloride and silver chloride.

Examples of the metal acetates include copper acetate, silver acetate, and palladium acetate.

Examples of the metal sulfates include copper sulfate and zinc sulfate.

Examples of the metal complexes include ferrocyanate-ferricyanate and ferrocene-ferricinium ion.

Examples of the sulfur compounds include polysodium sulfide and alkylthiol-alkyldisulfide.

Examples of the ionic liquids disclosed in Inorg. Chem. 35 (1996) 1168 include viologen dyes, hydroquinone, etc., 1,2-dimethyl-3-n-propylimidazolinium iodide, 1-methyl-3-n-hexylimidazolinium iodide, 1,2-dimethyl-3-ethylimidazoliumtrifluoromethane sulfonic acid salt, 1-methyl-3-butylimidazoliumnonafluorobutyl sulfonic acid salt, and 1-methyl-3-ethylimidazoliumbis(trifluoromethyl)sulfonylimide.

Examples of the lithium compounds include lithium trifluoromethane sulfonyl imide, and lithium diisopropyl imide.

Examples of the basic compounds include pyridine, 4-t-butylpyridine, benzimidazole, and compounds represented by General Formula (A) below. Among the above-listed examples, compounds represented by General Formula (A) are preferable. When any of compounds represented by General Formula (A) below is added to the organic hole-transport material, internal resistance of the photoelectric conversion element becomes high, loss of current due to weak light, such as room light, can be reduced, and the higher open voltage can be obtained. Therefore, use of such compounds is advantageous.

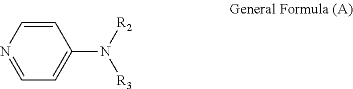

In General Formula (A), R₂ and R₃ are each a substituted or unsubstituted alkyl group or aromatic hydrocarbon group, and may be identical or different, and moreover R₂ and R₃ may be bonded to each other to form a substituted or unsubstituted heterocyclic group including a nitrogen atom.

Compounds represented by General Formula (A) are not particularly limited and may be appropriately selected depending on the intended purpose. Examples of compounds represented by General Formula (A) include compounds represented by Structural Formulae (A-1) to (A-9) below.

Note that, Japan Chemical Substance Dictionary Numbers of the compounds represented by Structural Formulae (A-1) to (A-5) are as follows.

<Compound No. 1-1, Japan Chemical Substance Dictionary No.: J31.394G>

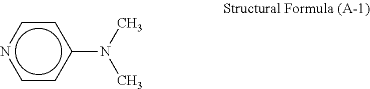

<Compound No. 1-2, Japan Chemical Substance Dictionary No.: J2.748.250C>

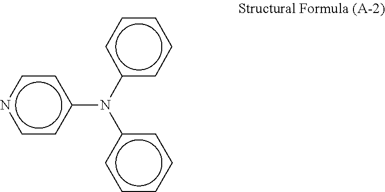

<Compound No. 1-3, Japan Chemical Substance Dictionary No.: J174K>

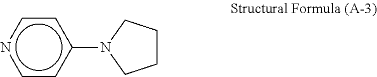

<Compound No. 1-4, Japan Chemical Substance Dictionary No.: J880.4591>

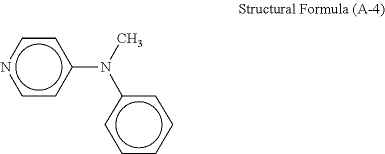

<Compound No. 1-5, Japan Chemical Substance Dictionary No.: J1.983.963J>

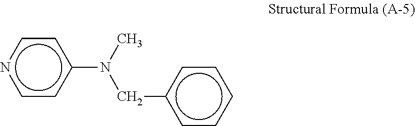

<Compound No. 1-6>

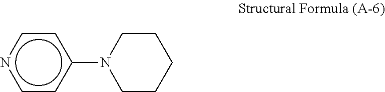

<Compound No. 1-7>

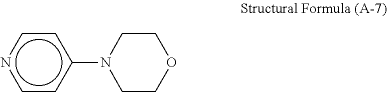

<Compound No. 1-8>

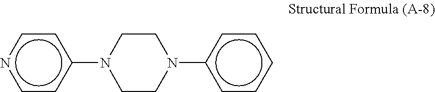

### <Compound No. 1-9>

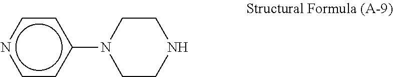

The compound represented by Structural Formula (A-1), which is a compound represented by General Formula (A), itself has been known. Moreover, it has been known that part of the compound is used as a basic compound in a liquid dye-sensitized solar cell using an iodine electrolyte.

However, it has also been known that high open voltage is obtained, but a short-circuit current density is significantly reduced, and photoelectric conversion characteristic is significantly deteriorated, when the basic compound is used in a known liquid dye-sensitized solar cell using an iodine electrolyte.

When the basic compound is used in a solid dye-sensitized solar sell using the organic hole-transport material as a material of the hole-transport layer, a reduction amount of the short-circuit current density is small, and high open voltage can be obtained, and therefore excellent photoelectric conversion characteristic can be obtained. Moreover, use of the basic compound gives a significant advantage in photoelectric conversion with weak light, such as room light, about which not so many examples have been reported.

An amount of a compound represented by General Formula (A) in the hole-transport layer is preferably 1 part by mass or greater but 20 parts by mass or less, and more preferably 5 parts by mass or greater but 15 parts by mass or less, relative to 100 parts by mass of the organic hole-transport material.

In view of improving conductivity, an oxidizing agent may be added for changing part of the organic hole-transport material to a radical cation.

Examples of the oxidizing agent include tris(4-bromophenyl)aminium hexachloroantimonate, silver hexafluoroantimonate, nitrosonium tetrafluoroborate, silver nitrate, and cobalt complex-based compounds.

There is no need that the entire organic hole-transport material be oxidized by addition of the oxidizing agent, as long as only part of the organic hole-transport material is oxidized. Moreover, the added oxidizing agent may be removed from or not removed from the system after addition.

The hole-transport layer can be formed directly on the electron-transport layer including the photosensitizing compound.

A production method of the hole-transport layer is not particularly limited and may be appropriately selected depending on the intended purpose. Examples of the production method include: a method where a thin film is formed in vacuum, such as vacuum vapor deposition; and wet film-forming methods. Among the above-listed examples, the wet film-forming methods are preferable in view of production cost, and a method for coating on the electron-transport layer is preferable.

When the wet film-forming method is used, a coating method is not particularly limited, and the wet film-forming method can be performed according to any of methods known in the art. Examples of the wet film-forming methods include dipping, spraying, wire-bar coating, spin coating, roller coating, blade coating, and gravure coating. As a wet printing method, moreover, various methods, such as letterpress, offset, gravure, intaglio, rubber plate, and screen printing, can be used. Moreover, a film may be formed in a supercritical fluid, or a subcritical fluid having a temperature and pressure lower than a critical point.

The supercritical fluid is not particularly limited and may be appropriately selected depending on the intended purpose, as long as the supercritical fluid is a fluid exists as a non-condensable high-density fluid in temperature and pressure ranges higher than a limit (critical point) until which a gas and a liquid can coexist, and even when compressed, does not condense but is maintained at higher than or equal to a critical temperature and higher than or equal to a critical pressure. However, a supercritical fluid having a low critical temperature is preferable.

Examples of the supercritical fluid include carbon monoxide, carbon dioxide, ammonia, nitrogen, water, alcohol solvents, hydrocarbon solvents, halogen solvents, and ether solvents.

Examples of the alcohol solvents include methanol, ethanol, and n-butanol.

Examples of the hydrocarbon solvents include ethane, propane, 2,3-dimethylbutane, benzene, and toluene.

Examples of the halogen solvents include methylene chloride, and chlorotrifluoromethane.

Examples of the ether solvents include dimethyl ether.

The above-listed solvents may be used alone or in combination.

Among the above-listed solvent, carbon dioxide is preferable because carbon dioxide has a critical pressure of 7.3 MPa and a critical temperature of 31° C., and hence can form a supercritical state easily and is incombustible and easy to handle.

The subcritical fluid is not particularly limited and may be appropriately selected depending on the intended purpose, as long as the subcritical fluid exists as a high-pressure liquid in temperature and pressure ranges near critical points.

The above-listed compounds as the supercritical fluid can be suitably used as the subcritical fluid.

A critical temperature and a critical pressure of the supercritical fluid are not particularly limited and may be appropriately selected depending on the intended purpose. However, the critical temperature is preferably −273° C. or higher but 300° C. or lower and more preferably 0° C. or higher but 200° C. or lower.

In addition to the supercritical fluid and the subcritical fluid, an organic solvent and an entrainer may further be used in combination. Addition of an organic solvent and an entrainer makes it easier to adjust solubility to the supercritical fluid.

The organic solvent is not particularly limited and may be appropriately selected depending on the intended purpose. Examples of the organic solvent include ketone solvents, ester solvents, ether solvents, amide solvents, halogenated hydrocarbon solvents, and hydrocarbon solvents.

Examples of the ketone solvents include acetone, methyl ethyl ketone, and methyl isobutyl ketone.

Examples of the ester solvents include ethyl formate, ethyl acetate, and n-butyl acetate.

Examples of the ether solvent include diisopropyl ether, dimethoxy ethane, tetrahydrofuran, dioxolane, and dioxane.

Examples of the amide solvents include N,N-dimethylformamide, N,N-dimethylacetamide, and N-methyl-2-pyrrolidone.

Examples of the halogenated hydrocarbon solvents include dichloromethane, chloroform, bromoform, methyl iodine, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

The above-listed solvents may be used alone or in combination.

Note that, a pressing process may be performed after disposing the organic hole-transport material on the electron-transport layer including the electron-transport material to which the photosensitizing compound is adsorbed. It is considered that the pressing process makes close adhesion of the organic hole-transport material with the electron-transport layer that is a porous electrode, hence efficiency is improved.

A method for the pressing process is not particularly limited and may be appropriately selected depending on the intended purpose. Examples of the pressing process include press forming using a flat plate, such as an IR tablet molding machine, and roll pressing using a roller.

Pressure for the pressing is preferably 10 kgf/cm² or greater, and more preferably 30 kgf/cm² or greater.

A duration for the pressing process is not particularly limited and may be appropriately selected depending on the intended purpose. The duration for the pressing process is preferably 1 hour or shorter. Moreover, heat may be applied during the pressing process.

A release agent may be disposed between a press and an electrode at the time of the pressing process.

Examples of the release agent include fluororesins such as polytetrafluoroethylene, polychlorotrifluoroethylene, tetrafluoroethylene-hexafluoropropylene copolymers, perfluoroalkoxy fluoride resins, polyvinylidene fluoride, ethylene-tetrafluoroethylene copolymers, ethylene-chlorotrifluoroethylene copolymers, and polyvinyl fluoride. The above-listed examples may be used alone or in combination.

After performing the pressing process, a metal oxide may be disposed between the organic hole-transport material and the second electrode before the second electrode is disposed.

Examples of the metal oxide include molybdenum oxide, tungsten oxide, vanadium oxide, and nickel oxide. The above-listed metal oxides may be used alone or in combination. Among the above-listed metal oxides, molybdenum oxide is particularly preferable.

A method for disposing the metal oxide on the hole-transport layer is not particularly limited and may be appropriately selected depending on the intended purpose. Examples of the method include: a method where a thin film is formed in vacuum, such as sputtering, and vacuum vapor deposition; and wet film-forming methods.

The wet film-forming method is preferably a method where a paste, in which a powder or sol of metal oxide is dispersed, is prepared, and the paste is applied onto the hole-transport layer.

In the case where the wet film-forming method is used, a coating method is not particularly limited and may be performed according to any of methods known in the art. Examples of the coating method include dipping, spraying, wire-bar coating, spin coating, roller coating, blade coating, and gravure coating. As a wet printing method, moreover, various methods, such as letterpress, offset, gravure, intaglio, rubber plate, and screen printing, can be used.

An average thickness of the coated metal oxide is preferably 0.1 nm or greater but 50 nm or less, and more preferably 1 nm or greater but 10 nm or less.

### <Second Electrode>

The second electrode may be formed on the hole-transport layer, or on the metal oxide of the hole-transport layer. Moreover, an electrode identical to the first electrode can be typically used as the second electrode, and the second electrode does not always need a support, when the second electrode has a structure where a strength and sealability of the second electrode are sufficiently maintained.

Examples of a material of the second electrode include metals, carbon compounds, conductive metal oxides, and conductive polymers.

Examples of the metals include platinum, gold, silver, copper, and aluminium.

Examples of the carbon compounds include graphite, fullerene, carbon nanotubes, and graphene.

Examples of the conductive metal oxides include ITO, FTO, and ATO.

Examples of the conductive polymers include polythiophene, and polyaniline.

The above-listed materials may be used alone or in combination.

The second electrode may be formed on the hole-transport layer by an appropriate method, such as coating, laminating, vapor deposition, CVD, and bonding, depending on a material for use or the hole-transport layer for use.

In the photoelectric conversion element of the present disclosure, the first electrode, or the second electrode, or both are substantially transparent. It is preferable in the present disclosure that the first electrode side of the photoelectric conversion element is transparent, and incident light enters from the first electrode side. In this case, a material that reflects light is preferably used for the side of the second electrode. As the material that reflects light, glass or a plastic to which metal or conductive oxide is deposited through vapor deposition, or a metal thin film is preferably used. Moreover, it is also effective that an anti-reflection layer is disposed at the side from which incident light enters.

### <Second Substrate>

The second substrate is not particularly limited, and can be appropriately selected from substrates known in the art. Examples of the second substrate include glass, transparent plastic plates, transparent plastic films, and inorganic transparent crystals.

A convex-concave region may be formed on the joined area between the second substrate and the sealing member. A formation method of the convex-concave region is not particularly limited and may be appropriately selected depending on the intended purpose. Examples of the formation method include sand blasting, water blasting, using sand paper, chemical etching, and laser processing.

As a method for enhancing adhesion between the second substrate and the sealing member, for example, organic matter on the surface of the second substrate may be removed, or hydrophilicity may be improved. A method for removing the organic matter on the surface of the second substrate is not particularly limited and may be appropriately selected depending on the intended purpose. Examples of the method include UV ozone cleaning, and oxygen plasma cleaning.

### <Sealing Member>

The sealing member is not particularly limited and may be appropriately selected depending on the intended purpose, as long as the sealing member is a member configured to inhibit entry of water vapor present outside. Examples of the sealing member include low-melting-point fritted glass, UV curable resins (e.g., epoxy resins and acrylic resins), and thermoset resins. The above-listed examples may be used alone or in combination. In addition to the constitutional materials mentioned above, a desiccant may be blended in order to inhibit entry of water vapor even better.

Examples of the desiccant include inorganic water-absorbing materials, such as calcium oxide and silica gel. Moreover, gap filler may be blended in order to control an average thickness of the sealing member.

The gap filler is selected from particles having a diameter of typically from several micrometers through several tens micrometers. As the gap filler, organic resin gap filler, or inorganic gap filler, such as silica gel, is used. Moreover, additives, such as a silane coupling agent reactive with hydroxyl groups, may be blended in order to securely bond between the substrate and the interface of the sealing member.

An arrangement of the sealing member is not particularly limited and may be appropriately selected depending on the intended purpose, as long as the sealing member is disposed between the first electrode and the second substrate and is arranged in a manner that at least part of the sealing member is in contact with the first substrate through the through section of the first electrode or the through section of the hole-blocking layer. Since the sealing member is in contact with the first substrate through the through section, in the present disclosure, a contact area between the first electrode and the first substrate with the sealing member is large, and adhesion between the first electrode and the first substrate with the sealing member is enhanced. Therefore, deterioration caused by water vapor present outside entering the element is prevented, and reduction in photoelectric conversion efficiency can be prevented even in a high-temperature and high-humidity environment.

In the case where the sealing member includes, for example, a silane coupling agent configured to react with a hydroxyl group to bond, adhesion of the sealing member is stronger when the sealing member is brought into contact with a glass substrate serving as the first substrate having the large number of hydroxyl groups as surface functional groups than when the sealing member is brought into contact with an ITO conductive film serving as the first electrode. Accordingly, a sealing effect is improved.

Moreover, the sealing member may be present between the second electrode and the second substrate, as long as the sealing member is arranged in a manner that at least part of the sealing member is in contact with the first substrate through the through section of the first electrode or the through section of the hole-blocking layer.

Moreover, a passivation layer may be disposed between the second electrode and the sealing member. The passivation layer is not particularly limited and may be appropriately selected depending on the intended purpose, as long as the passivation layer is disposed in a manner that the sealing member is not to be in contact with the second electrode. The passivation layer is preferably aluminium oxide, silicon nitride, and silicon oxide.

A formation method of the sealing member is not particularly limited, and may be selected from methods known in the art. As the formation method, various methods, such as a dispensing method, wire-bar coating, spin coating, roller coating, blade coating, gravure coating, letterpress printing, offset printing, intaglio printing, rubber plate printing, and screen printing, can be used.

### <Hole-Blocking Layer>

Typically, the hole-blocking layer is disposed in order to suppress a fall in electric power due to contact of an electrolyte with an electrode and consequent recombination between holes in the electrolyte and electrons (so-called back electron transfer). The effect of the hole blocking layer is particularly remarkable in solid dye-sensitized solar cells. This is because a speed of recombination (back electron transfer) between holes in hole-transport materials and electrons in surfaces of electrodes is higher in solid dye-sensitized solar cells using, for example, organic hole-transport materials than in wet dye-sensitized solar cells using electrolytic solutions.

A material of the hole-blocking layer is not particularly limited and may be appropriately selected depending on the intended purpose, as long as the material is a material that is transparent to visible light and is an electron-transport material. Examples of the material of the hole-blocking layer include titanium oxide, niobium oxide, magnesium oxide, aluminium oxide, zinc oxide, tungsten oxide, and tin oxide. The above-listed materials may be used alone or in combination as a laminate or a mixture.

A structure of the hole-blocking layer is not particularly limited and may be appropriately selected depending on the intended purpose. The hole-blocking layer preferably includes a through section connected to the through section of the first electrode. When the hole-blocking layer includes a through section, the sealing member can be in contact with the first substrate through the through section of the hole-blocking layer and the through section of the first electrode. As a result, a joined area between the first electrode, the first substrate, and the hole-blocking layer with the sealing member becomes large, and adhesion is enhanced, and therefore a sealing effect is sufficiently exhibited. Consequently, a fall in photoelectric conversion efficiency can be suppressed even in a high-temperature and high-humidity environment.

The hole-blocking layer desirably has high internal resistance in order to suppress loss current under indoor light. Therefore, a film-forming method of the hole-blocking layer is also important matter to consider.

Typical examples of a film-forming method of the hole-blocking layer include a sol-gel method that is a wet film-forming method. However, a density of a film formed by the sol-gel method is low and loss current cannot be sufficiently suppressed. Therefore, a dry film-forming method, such as sputtering, is preferable as the film-forming method, and the dry film-forming method is advantageous because a resultant film has sufficiently high density, and loss current can be suppressed.

An average thickness of the hole-blocking layer is not particularly limited and may be appropriately selected depending on the intended purpose. The average thickness of the hole-blocking layer is preferably 5 nm or greater but 1 μm or less. In a wet film-forming method, the average thickness of the hole-blocking layer is more preferably 500 nm or greater but 700 nm or less. In a dry film-forming method, the average thickness of the hole-blocking layer is more preferably 10 nm or greater but 30 nm or less.

### <Applications>

The photoelectric conversion element of the present disclosure is an element configured to convert optical energy into electric energy, or an element configured to convert electric energy into optical energy. Specific examples of the photoelectric conversion element of the present disclosure include solar cells, and photodiodes.

The photoelectric conversion element of the present disclosure can be applied to a power supply device, when combined with, for example, a circuit board configured to control a generated current. Examples of devices utilizing the power supply device include calculators and watches. Other than the examples listed above, a power supply device including the photoelectric conversion element of the present disclosure can be also applied to mobile phones, electronic organizers, and electronic paper. The power supply device including the photoelectric conversion element of the present disclosure can also be used as an auxiliary power supply intended for extending a continuously usable time of chargeable or dry cell-operated electric appliances.

Next, examples of the photoelectric conversion element of the present disclosure are described with reference with drawings.

In the drawings, identical reference numerals are given to identical constitutional members, and duplicated descriptions may be omitted. Moreover, the number, positions, or shapes of the constitutional members below is not limited to the embodiments below, and the preferably number, positions, shapes for carrying out the present disclosure can be used.

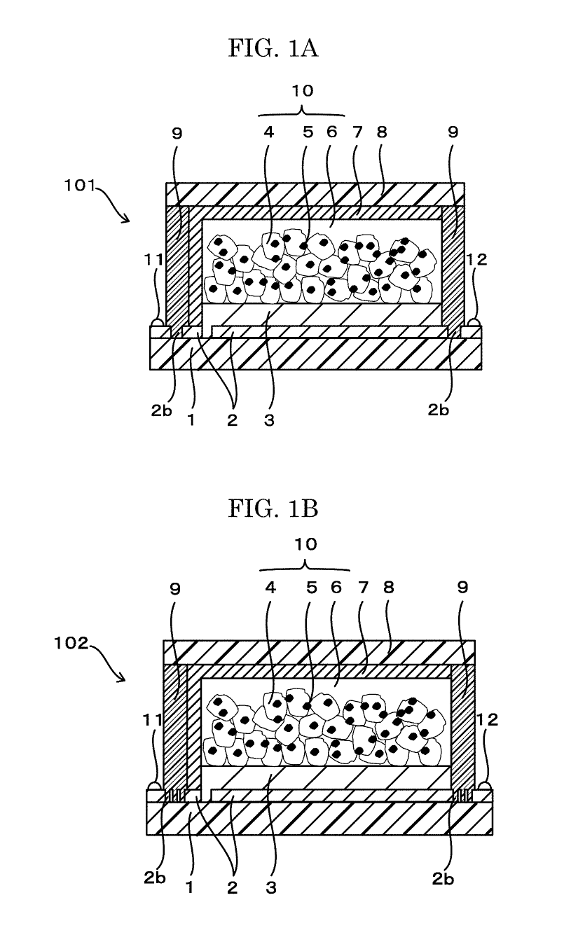

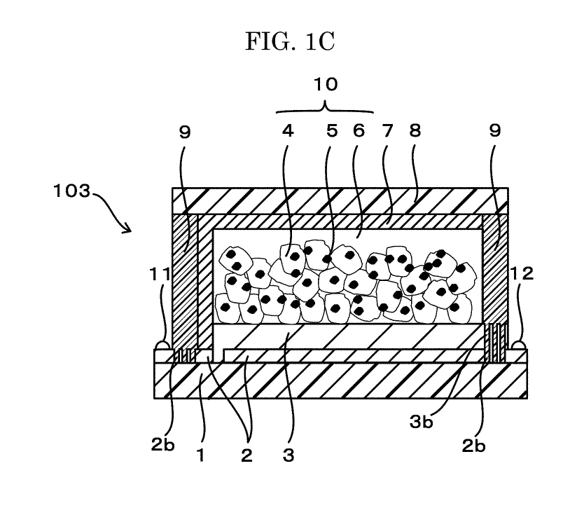

FIG. 1A is a schematic cross-sectional view illustrating one example of the photoelectric conversion element of the present disclosure.

In the photoelectric conversion element 101, as illustrated in FIG. 1A, a first electrode 2 is formed on a first substrate 1, a hole-blocking layer 3 is formed on the first electrode 2, a photoelectric conversion layer 10 is formed on the hole-blocking layer 3, a second electrode 7 is formed on the photoelectric conversion layer 10, and a second substrate 8 is formed on the second electrode 7.

The photoelectric conversion layer 10 includes an electron-transport layer 4 and a hole-transport layer 6, and a photosensitizing compound 5 is adsorbed on an electron-transport material of the electron-transport layer 4.

In such a photoelectric conversion element 101, a sealing member 9 configured to seal at least the photoelectric conversion layer 10 is disposed between the first electrode 2 and the second substrate 8, the first electrode 2 includes a through section 2b, and the sealing member 9 is in contact with the first substrate 1 through the through section 2b.

FIGS. 1B and 1C are schematic cross-sectional views illustrating another examples of the photoelectric conversion element of the present disclosure.

FIG. 1B is an identical schematic cross-sectional view to FIG. 1A, except that a plurality of the through sections 2b are disposed.

FIG. 1C is an identical schematic cross-sectional view to FIG. 1B, except that a through section 3b is also disposed in the hole-blocking layer 3, the through section 3b and the through section 2b are connected, and the sealing member 9 is in contact with the first substrate 1 through the through section 3b and the through section 2b.

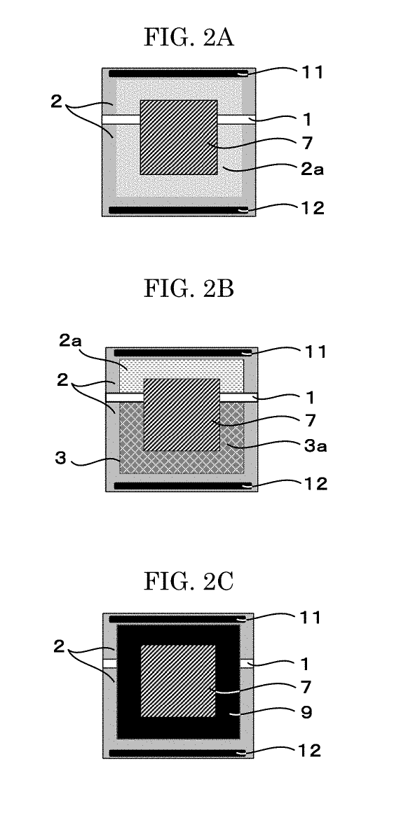

FIGS. 2A and 2B are schematic top views illustrating positions of the through sections in the photoelectric conversion elements illustrated in FIGS. 1A and 1B.

FIG. 2C is a schematic top view illustrating a position of a sealing member in the photoelectric conversion element illustrated in FIGS. 1A to 1C.

As illustrated in FIG. 2A, the through section 2a of the first electrode 2 is disposed at the position where at least the sealing member is disposed.

As illustrated in FIG. 2B, the through section 3a of the hole-blocking layer 3 is disposed with overlapping with at least a side of the through section 2a where the photoelectric conversion layer 10 is formed, within the through section 2a of the first electrode 2 illustrated in FIG. 2A.

As illustrated in FIG. 2C, the sealing member 9 is disposed in a manner that the sealing member 9 is overlapped with the through section 2a and the through section 3a illustrated in FIGS. 2A and 2B.

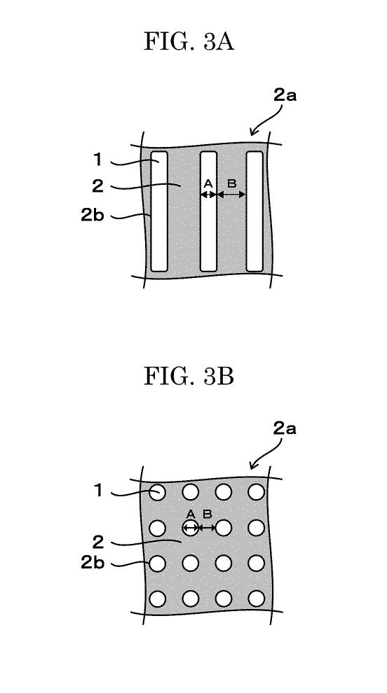

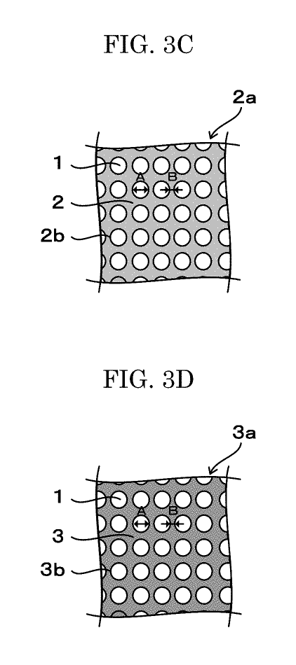

FIG. 3A is an enlarged top view illustrating one example of a through section in the photoelectric conversion element of the present disclosure. FIGS. 3B to 3D are enlarged top views illustrating another examples of a through section in the photoelectric conversion element of the present disclosure.

As illustrated in FIG. 3A, linear through holes 2b are disposed in the through section 2a of the first electrode 2.

As illustrated in FIG. 3B, through holes 2b are disposed in a dot pattern with even gaps in the through section 2a of the first electrode 2.

As illustrated in FIG. 3C, through holes 2b are disposed in a dot pattern with even gaps in the through section 2a of the first electrode 2.

As illustrated in FIG. 3D, through holes 3b are disposed in a dot pattern with even gaps in the through section 3a of the hole-blocking layer 3.

### EXAMPLES

The present disclosure will be described in more detail by way of the following Examples and Comparative Examples. However, the present disclosure should not be construed as being limited to these Examples.

### Example 1

### <Production of Titanium Oxide Semiconductor Electrode (Electron-Transport Layer)>

On an ITO-coated glass, which was an integrated body formed by disposing an ITO conductive film serving as the first electrode on a glass substrate serving as the first substrate, a dense hole-blocking layer formed of titanium oxide was formed by reactive sputtering by oxygen gas using a target formed of metal titanium.

Next, 3 g of titanium oxide (P90, available from Nippon Aerosil Co., Ltd.), 0.2 g of acetyl acetone, and 0.3 g of a surfactant (polyoxyethylene octylphenyl ether, available from Wako Pure Chemical Industries, Ltd.) were treated by a bead mill together with 5.5 g of water and 1.0 g of ethanol for 12 hours, to thereby obtain a titanium oxide dispersion liquid. To the obtained titanium oxide dispersion liquid, 1.2 g of polyethylene glycol (#20,000, available from Wako Pure Chemical Industries, Ltd.) was added to thereby produce a paste.

The obtained paste was applied onto the hole-blocking layer in a manner that an average thickness of the applied paste was to be 1.5 μm, and the applied paste was dried at room temperature, followed by firing in the air at 500° C. for 30 minutes, to thereby form a porous electron-transport layer. In the manner as described above, a titanium oxide semiconductor electrode was produced.

### <Production of Photoelectric Conversion Layer>

After immersing the titanium oxide semiconductor electrode in D358, represented by Structural Formula (3) below and available from MITSUBISHI PAPER MILLS LIMITED (0.5 mM, acetonitrile/t-butanol (volume ratio 1:1) solution), the resultant titanium oxide semiconductor electrode was left to stand in the dark for 1 hour to allow the photosensitizing material adsorbed on the titanium oxide semiconductor electrode.

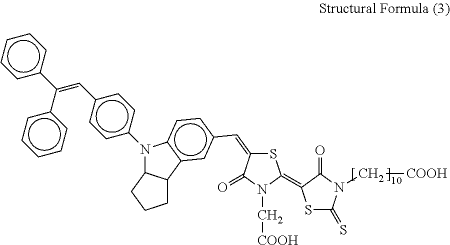

Next, to 1 mL of a chlorobenzene solution including 183.8 mg of an organic hole-transport material represented by Structural Formula (4) below (name: 2,2′,7,7′-tetrakis(N,N-di-p-methoxyphenylamino)-9,9′-spirobifluorene, product number: SHT-263, available from Merck KGaA; CAS No. 207739-72-8), 12.87 mg of a compound represented by Structural Formula (5) below (lithium bis(trifluoromethane sulfonyl)imide, available from KANTO CHEMICAL CO., LTD.) and 22.98 mg of a compound represented by General Formula (A) presented earlier were added to prepare a hole-transport layer coating liquid.

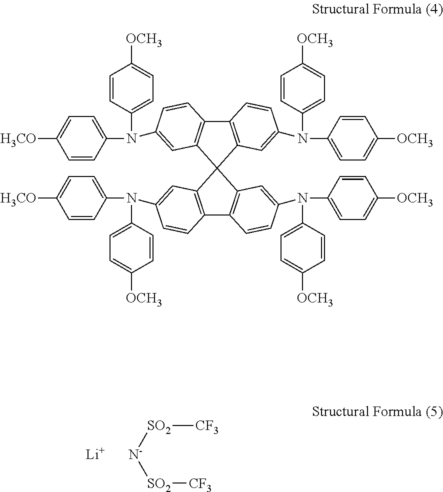

Next, the hole-transport layer coating liquid was applied onto the semiconductor electrode bearing the photosensitizing material by spin coating to form a hole-transport layer. In the manner as described above, a photoelectric conversion layer was formed.

Next, 100 nm of silver was disposed on the photoelectric conversion layer by vacuum vapor deposition to form a second electrode.

### <Sealing>

The ITO conductive film serving as the first electrode was removed through impact stripping by laser along a periphery of the photoelectric conversion layer, to form through holes. A shape of each of the through holes was to be a line shape, the minimum opening length A of the through holes was to be 25 μm, and the minimum distance B between the through holes adjacent to each other was to be 50 μm. As a laser device, a laser patterning device available from OMRON LASERFRONT INC., as an oscillator, a third harmonic generation (THF) oscillator was used, an output was 120 mW, and a wavelength was 349 nm. The minimum opening length A of the through holes and the minimum distance B between the through holes adjacent to each other can be set to the predetermined values by controlling processing frequency, processing speed, and processing pitch of the laser patterning device. An UV curable resin (TB3035B, available from ThreeBond Holdings Co., Ltd.) was applied on the through section by a dispenser (2300N, available from SAN-EI TECH Ltd.), and the resultant was sandwiched with cover glass, followed by performing UV irradiation to cure the UV curable resin, to thereby obtain a photoelectric conversion element of Example 1.

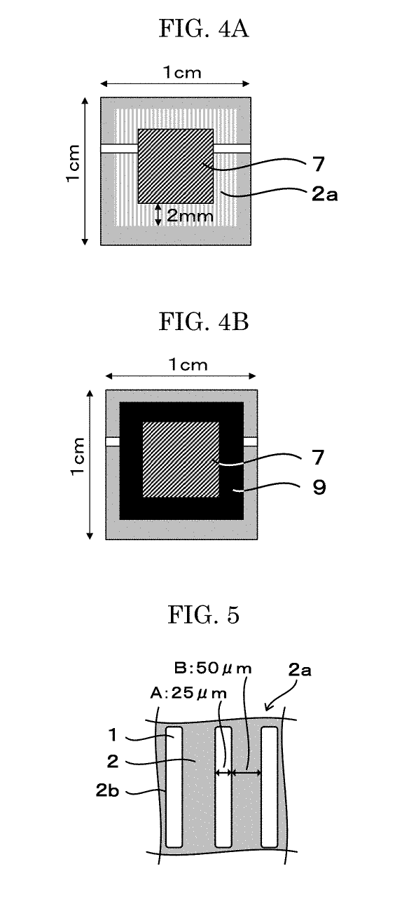

Note that, FIG. 4A is a schematic top view illustrating a through section in the photoelectric conversion element of Example 1, and FIG. 4B is a schematic top view illustrating a state after disposing a sealing member to the through section in the photoelectric conversion element of Example 1. Moreover, FIG. 5 is an enlarged top view illustrating the through section in the photoelectric conversion element of Example 1.

### <Evaluation of Photoelectric Conversion Element>

The obtained photoelectric conversion element was left to stand in a high-temperature and high-humidity environment (60° C., 90% RH) for 500 hours, and a photoelectric conversion efficiency of the photoelectric conversion element under white LED irradiation (1,000 Lux, 0.24 mW/cm²) was measured. A result is presented in Table 1.

For the measurement of the photoelectric conversion efficiency, a high color-rendering LED desk lamp (CDS-90a, available from Cosmotechno. Co., Ltd., study mode) was used as the white LED and a solar cell evaluation system (As-510-PV03, available from NF CORPORATION) was used as the evaluator.

### Example 2

A photoelectric conversion element of Example 2 was produced in the same manner as in Example 1, except that the processing by the laser patterning device was performed in a manner that the minimum opening length A was to be 25 μm, and the minimum distance B was to be uneven (to have uneven gaps). The obtained photoelectric conversion element was evaluated in the same manner as in Example 1. A result is presented in Table 1.

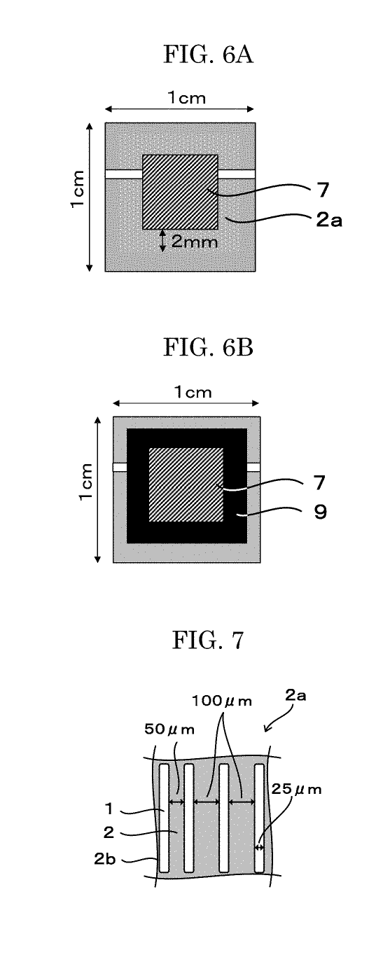

Note that, FIG. 6A is a schematic top view illustrating the through section in the photoelectric conversion element of Example 2, and FIG. 6B is a schematic top view illustrating a state after disposing a sealing member to the through section in the photoelectric conversion element of Example 2. Moreover, FIG. 7 is an enlarged top view illustrating the through section in the photoelectric conversion element of Example 2.

### Example 3

A photoelectric conversion element of Example 3 was produced in the same manner as in Example 1, except that the processing by the laser patterning device was performed in a manner that a shape of each through hole was to be a circle, the minimum opening length A was to be 25 μm, and the minimum distance B was to be 50 μm. The obtained photoelectric conversion element was evaluated in the same manner as in Example 1. The result is presented in Table 1.

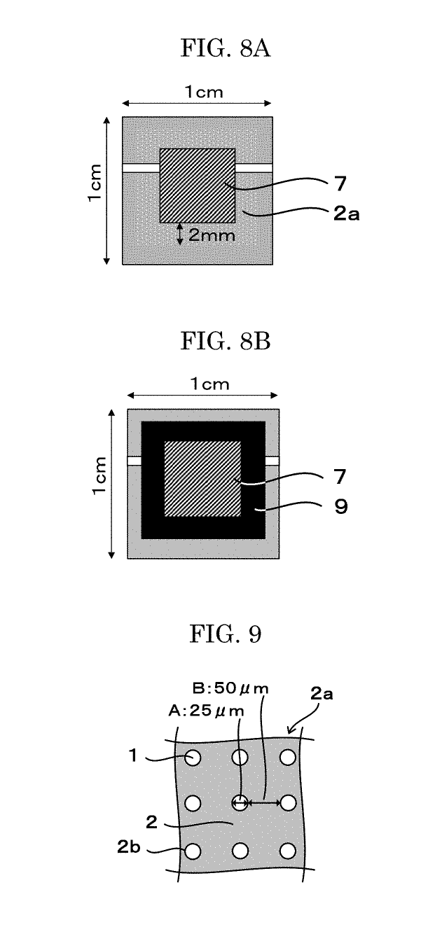

Note that, FIG. 8A is a schematic top view illustrating a through section in the photoelectric conversion element of Example 3, and FIG. 8B is a schematic top view illustrating a state after disposing a sealing member to the through section in the photoelectric conversion element of Example 3. Moreover, FIG. 9 is an enlarged top view illustrating the through section in the photoelectric conversion element of Example 3.

### Example 4

A photoelectric conversion element of Example 4 was produced in the same manner as in Example 1, except that the processing by the laser patterning device was performed in a manner that a shape of each through hole was to be a circle, the minimum opening length A was to be 25 μm, and the minimum distance B was to be 25 μm. The obtained photoelectric conversion element was evaluated in the same manner as in Example 1. The result is presented in Table 1.

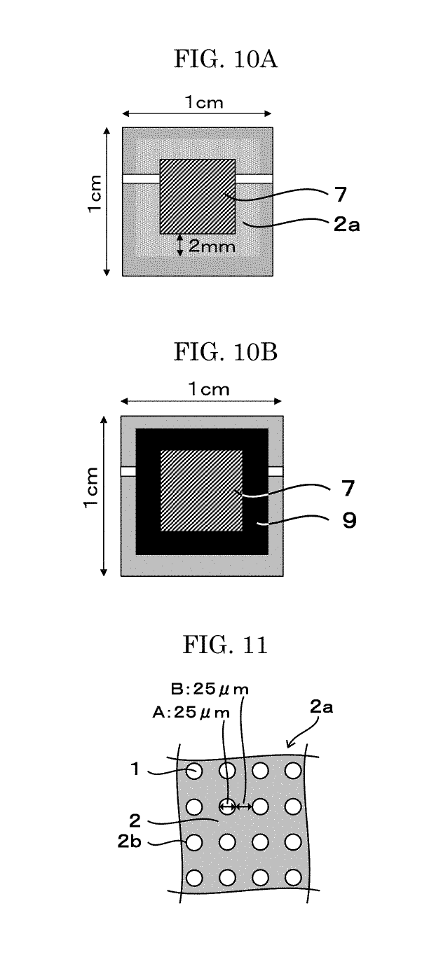

Note that, FIG. 10A is a schematic top view illustrating a through section in the photoelectric conversion element of Example 4, and FIG. 10B is a schematic top view illustrating a state after disposing a sealing member to the through section in the photoelectric conversion element of Example 4. Moreover, FIG. 11 is an enlarged top view illustrating the through section in the photoelectric conversion element of Example 4.

### Example 5

A photoelectric conversion element of Example 5 was produced in the same manner as in Example 1, except that the processing by the laser patterning device was performed in a manner that a shape of each through hole was to be a circle, the minimum opening length A was to be 25 μm, and the minimum distance B was to be 10 μm. The obtained photoelectric conversion element was evaluated in the same manner as in Example 1. The result is presented in Table 1.

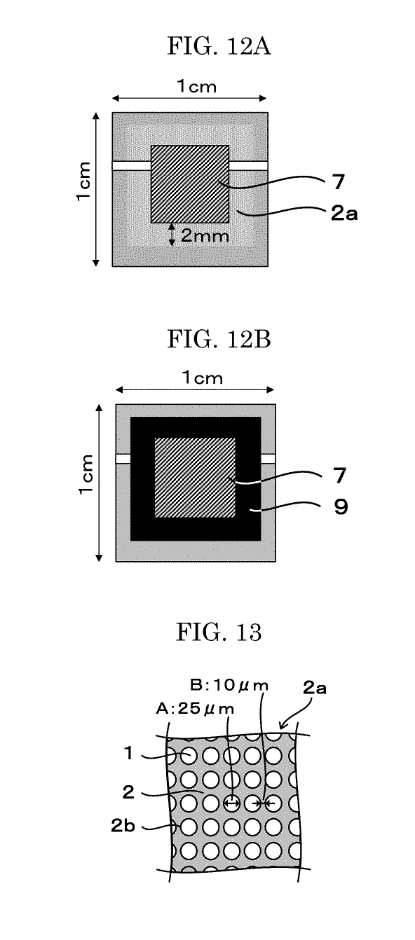

Note that, FIG. 12A is a schematic top view illustrating a through section in the photoelectric conversion element of Example 5, and FIG. 12B is a schematic top view illustrating a state after disposing a sealing member to the through section in the photoelectric conversion element of Example 5. Moreover, FIG. 13 is an enlarged top view illustrating the through section in the photoelectric conversion element of Example 5.

### Example 6

A photoelectric conversion element of Example 6 was produced in the same manner as in Example 4, except that a hole-blocking layer having an area identical to the through section at the side where the photoelectric conversion layer was provided, among the through sections of the ITO conductive film serving as the first electrode in Example 5, and a through section was disposed in the hole-blocking layer in the same manner as in the first electrode. The obtained photoelectric conversion element was evaluated in the same manner as in Example 4. The result is presented in Table 1.

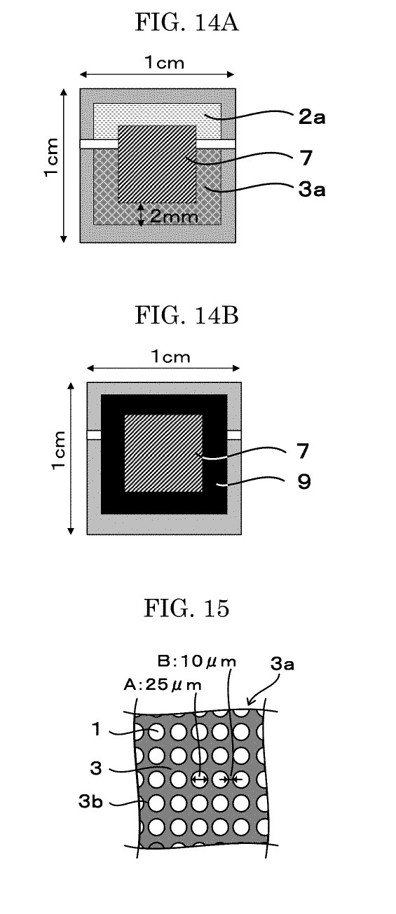

Note that, FIG. 14A is a schematic top view illustrating a through section in the photoelectric conversion element of Example 6, and FIG. 14B is a schematic top view illustrating a state after disposing a sealing member to the through section in the photoelectric conversion element of Example 6. Moreover, FIG. 15 is an enlarged top view illustrating the through section in the photoelectric conversion element of Example 6.

### Comparative Example 1

A photoelectric conversion element of Comparative Example 1 was produced in the same manner as in Example 1, except that the through section was not disposed. The obtained photoelectric conversion element was evaluated in the same manner as in Example 1. The result is presented in Table 2.

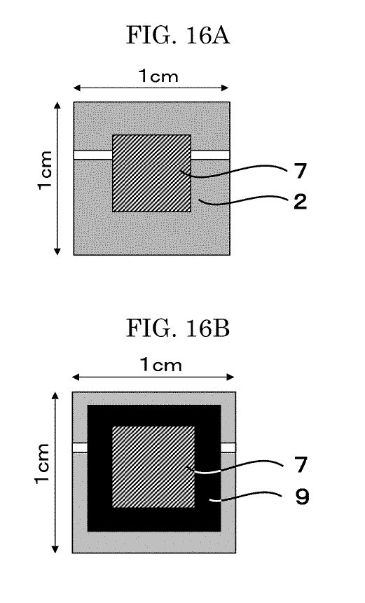

Note that, FIG. 16A is a schematic top view illustrating a through section in the photoelectric conversion element of Comparative Example 1, and FIG. 16B is a schematic top view illustrating a state after disposing a sealing member to the through section in the photoelectric conversion element of Comparative Example 1.

### Comparative Example 2

A photoelectric conversion element of Comparative Example 2 was produced in the same manner as in Example 1, except that processing by a laser patterning device was performed so that holes that did not pass through laser were formed in the ITO conductive film serving as the first electrode, a shape of each of the holes was a circular shape, the minimum opening length of the holes was 25 μm, and the minimum distance between holes was 10 μm. The obtained photoelectric conversion element was evaluated in the same manner as in Example 1. The result is presented in Table 2.

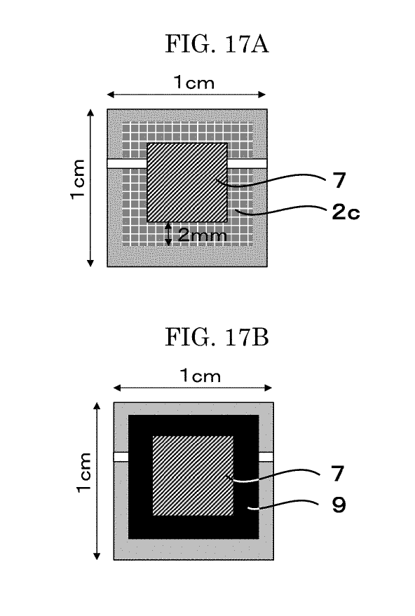

Note that, FIG. 17A is a schematic top view illustrating a hole section in the photoelectric conversion element of Comparative Example 2, and FIG. 17B is a schematic top view illustrating a state after disposing a sealing member to the hole section of the photoelectric conversion element of Comparative Example 2.

### Comparative Example 3

A photoelectric conversion element of Comparative Example 3 was produced in the same manner as in Example 1, except that a silver paste (JELCON RK series L2, available from JUJO CHEMICAL CO., LTD.) was applied onto the through section and the sealing member was not in contact with the first substrate. The obtained photoelectric conversion element was evaluated in the same manner as in Example 1. The result is presented in Table 2.

Note that, the silver paste was applied by screen printing, and dried at 80° C. for 30 minutes to form the silver film having an average thickness of 2 μm.

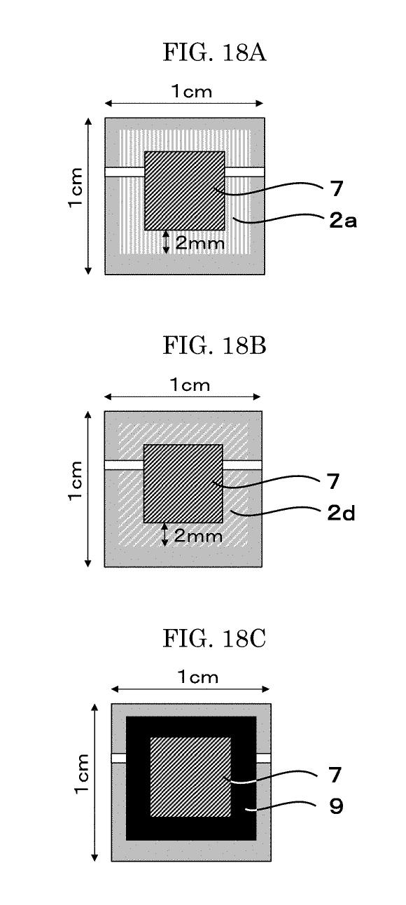

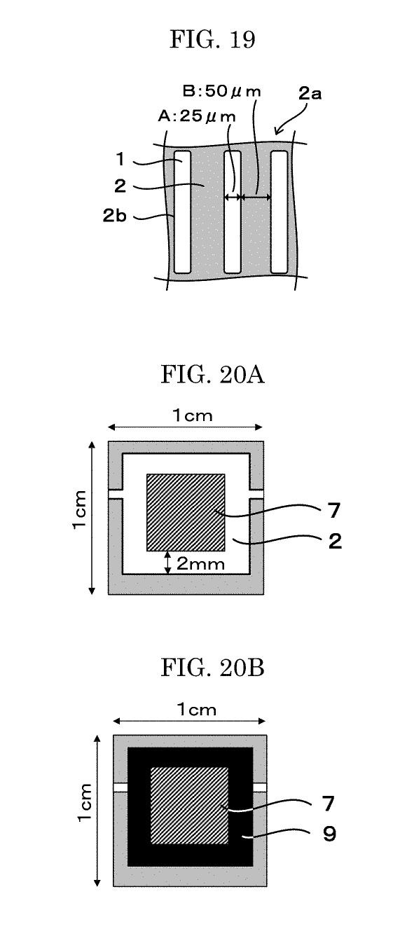

FIG. 18A is a schematic top view illustrating a through section in the photoelectric conversion element of Comparative Example 3, FIG. 18B is a schematic top view illustrating a state after applying a silver paste to the through section of the photoelectric conversion element of Comparative Example 3, and FIG. 18C is a schematic top view illustrating a state after disposing a sealing member after the application of the silver paste to the photoelectric conversion element of Comparative Example 3. Moreover, FIG. 19 is an enlarged top view illustrating the through section of the photoelectric conversion element of Comparative Example 3.

### Comparative Example 4

A photoelectric conversion element of Comparative Example 4 was produced in the same manner as in Example 1, except that all of the ITO conductive film serving as the first electrode was removed through impact stripping by laser along the periphery of the photoelectric conversion layer. The obtained photoelectric conversion element was evaluated in the same manner as in Example 1. Since all of the ITO conductive film was removed, the generated electricity could not be drawn outside. The result is presented in Table 2.

Note that, FIG. 20A is a schematic top view illustrating the photoelectric conversion element of Comparative Example 4, and FIG. 20B is a schematic top view illustrating a state after disposing a sealing member to the photoelectric conversion element of Comparative Example 4.

TABLE 1

| | | Examples | | | | | |
|---|---|---|---|---|---|---|---|
| | | 1 | 2 | 3 | 4 | 5 | 6 |
| Through | Presence | Yes | Yes | Yes | Yes | Yes | Yes |
| section | Disposed | First | First | First | First | First | First electrode |
| | layer | electrode | electrode | electrode | electrode | electrode | Hole-blocking |
| | | | | | | | layer |
| Through | Shape | Line | Line | Dot | Dot | Dot | Dot |
| holes | Arrangement | Even gaps | Uneven | Even gaps | Even gaps | Even gaps | Even gaps |
| | Minimum | 25 | 25 | 25 | 25 | 25 | 25 |
| | opening | | | | | | |
| | length A | | | | | | |
| | (μm) | | | | | | |
| | Minimum | 50 | NA | 50 | 25 | 10 | 10 |
| | distance B | | | | | | |
| | (μm) | | | | | | |
| | A > B | No | No | No | No | Yes | Yes |
| Sealing member is in contact | | Yes | Yes | Yes | Yes | Yes | Yes |
| with first substrate through | | | | | | | |
| through holes | | | | | | | |
| Initial | Open circuit | 0.95 | 0.96 | 0.95 | 0.95 | 0.95 | 0.95 |
| | voltage (V) | | | | | | |
| | Short circuit | 34.45 | 34.50 | 34.39 | 34.21 | 34.09 | 34.01 |
| | current | | | | | | |
| | (μA/cm²) | | | | | | |
| | Shape factor | 0.78 | 0.78 | 0.77 | 0.77 | 0.77 | 0.77 |
| | Photoelectric | 10.64 | 10.76 | 10.59 | 10.43 | 10.39 | 10.37 |
| | conversion | | | | | | |
| | efficiency (%) | | | | | | |
| After standing | Open circuit | 0.69 | 0.69 | 0.70 | 0.69 | 0.69 | 0.70 |
| high-temp. | voltage (V) | | | | | | |
| high-humidity | Short circuit | 39.11 | 39.02 | 39.63 | 40.15 | 40.34 | 40.42 |
| environment | current | | | | | | |
| | (μA/cm²) | | | | | | |
| | Shape factor | 0.65 | 0.64 | 0.64 | 0.64 | 0.64 | 0.63 |
| | Photoelectric | 7.31 | 7.18 | 7.40 | 7.39 | 7.42 | 7.43 |
| | conversion | | | | | | |
| | efficiency (%) | | | | | | |
| Evaluation | Fall rate (%) | 31.29 | 33.30 | 30.16 | 29.15 | 28.56 | 28.35 |
| result | | | | | | | |

TABLE 2

| | | Comparative Example | | | |
|---|---|---|---|---|---|
| | | 1 | 2 | 3 | 4 |
| Through | Presence | No | No | Yes | No |
| section | | | (convex-concave) | | (no first electrode) |
| | Disposed | NA | NA | First | NA |
| | layer | | | electrode | |
| Through | Shape | NA | NA | Line | NA |
| holes | Arrangement | NA | NA | Even gaps | NA |
| | Minimum | NA | NA | 25 | NA |
| | opening | | | | |
| | length A | | | | |
| | (μm) | | | | |
| | Minimum | NA | NA | 50 | NA |
| | distance B | | | | |
| | (μm) | | | | |
| | A > B | NA | NA | No | NA |
| Sealing member is in contact | | NA | No | No | No |
| with first substrate through | | | | | |
| through holes | | | | | |
| Initial | Open circuit | 0.95 | 0.94 | 0.94 | NA |
| | voltage (V) | | | | |
| | Short circuit | 34.52 | 34.42 | 34.15 | NA |
| | current | | | | |
| | (μA/cm²) | | | | |
| | Shape factor | 0.78 | 0.77 | 0.75 | NA |
| | Photoelectric | 10.66 | 10.38 | 10.03 | NA |
| | conversion | | | | |
| | efficiency (%) | | | | |
| After standing | Open circuit | 0.63 | 0.66 | 0.61 | NA |
| high-temp. | voltage (V) | | | | |
| high-humidity | Short circuit | 26.21 | 29.37 | 19.78 | NA |
| environment | current | | | | |
| | (μA/cm²) | | | | |
| | Shape factor | 0.60 | 0.64 | 0.59 | NA |
| | Photoelectric | 4.13 | 5.17 | 2.97 | NA |
| | conversion | | | | |
| | efficiency (%) | | | | |
| Evaluation | Fall rate (%) | 61.27 | 50.20 | 70.43 | NA |
| result | | | | | |

It was found from the results presented in Tables 1 and 2 that a fall in the photoelectric conversion efficiency of the photoelectric conversion elements of Examples 1 to 6 was suppressed compared to the photoelectric conversion elements of Comparative Examples 1 to 3. This was because the through section was disposed in the first electrode, and the sealing member was arranged to be in contact with the first substrate through the through section, and therefore a joined area between the first electrode and first substrate with the sealing member was large. Accordingly, adhesion of the sealing member with the first electrode and the first substrate was enhanced, and a sealing effect of an interface between the first electrode and the sealing member was improved.

It was clearly found out from Examples and Comparative Examples above that the photoelectric conversion element of the present disclosure exhibited excellent photoelectric conversion characteristic.

For example, embodiments of the present disclosure are as follows.

<1> A photoelectric conversion element including:
a first substrate;
a first electrode on the first substrate;
a photoelectric conversion layer on the first electrode;
a second electrode on the photoelectric conversion layer;
a second substrate on the second electrode; and
a sealing member disposed between the first electrode and the second substrate and configured to seal at least the photoelectric conversion layer,
the first electrode including a through section,
the sealing member being in contact with the first substrate through the through section.
<2> The photoelectric conversion element according to <1>, wherein the through section includes through holes disposed in a dot pattern with even gaps.
<3> The photoelectric conversion element according to <2>,
wherein the through holes satisfy a formula A>B, where A is a minimum opening length of the through hole and B is a minimum distance between the through holes adjacent to each other.
<4> The photoelectric conversion element according to <3>,
wherein the minimum opening length A is 5 μm or greater but 500 μm or less.
<5> The photoelectric conversion element according to <3> or <4>,
wherein the minimum distance B is 1 μm or greater but 400 μm or less.
<6> The photoelectric conversion element according to any one of <1> to <5>,
wherein an average thickness of the first electrode is 5 nm or greater but 100 μm or less.
<7> The photoelectric conversion element according to any one of <1> to <6>,
wherein an average thickness of the first electrode is 50 nm or greater but 10 μm or less.
<8> The photoelectric conversion element according to any one of <1> to <7>, further including a hole-blocking layer,
wherein the hole-blocking layer is disposed between the first electrode and the sealing member,
the hole-blocking layer includes a through section connected to the through section of the first electrode, and
the sealing member is in contact with the first substrate through the through section of the hole-blocking layer and the through section of the first electrode.
<9> The photoelectric conversion element according to any one of <1> to <8>,
wherein an average thickness of the hole-blocking layer is 5 nm or greater but 1 μm or less.
<10> The photoelectric conversion element according to any one of <1> to <9>,
wherein the photoelectric conversion layer includes an electron-transport layer and a hole-transport layer.
<11> The photoelectric conversion element according to <10>,
wherein an average thickness of the electron-transport layer is 100 nm or greater but 100 μm or less.
<12> The photoelectric conversion element according to <10> or <11>, wherein the electron-transport layer includes semiconductor particles.
<13> The photoelectric conversion element according to <12>, wherein a number average particle diameter of primary particles of the semiconductor particles is 1 nm or greater but 100 nm or less.
<14> The photoelectric conversion element according to <12> or <13>, wherein a duration for adsorbing a photosensitizing compound, a disaggregating agent, or both onto the semiconductor particles is 5 seconds or longer but 1,000 hours or shorter.
<15> The photoelectric conversion element according to any one of <10> to <14>,
wherein the electron-transport layer includes a photosensitizing compound.
<16> The photoelectric conversion element according to any one of <10> to <15>,
wherein the hole-transport layer includes an organic hole-transport material.
<17> The photoelectric conversion element according to <16>,
wherein the organic hole-transport material includes a compound represented by General Formula (A) below,

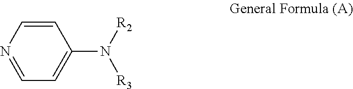

where, in General Formula (A), R₂ and R₃ are each a substituted or unsubstituted alkyl group or an aromatic hydrocarbon group, and are identical or different, and R₂ and R₃ may be bonded to each other to form a substituted or unsubstituted heterocyclic group including a nitrogen atom.
<18> The photoelectric conversion element according to <17>, wherein an amount of the compound represented by General Formula (A) in the hole-transport layer is 1 part by mass or greater but 20 parts by mass or less relative to 100 parts by mass of the organic hole-transport material.
<19> A solar cell including:
the photoelectric conversion element according to any one of <1> to <18>.

The photoelectric conversion element according to any one of <1> to <18> and the solar cell according to <19> can the above-mentioned various problems existing in the art, and can achieve the object of the present disclosure.

What is claimed is:

1. A photoelectric conversion element comprising:
a first substrate;
a first electrode on the first substrate;
a photoelectric conversion layer on the first electrode;
a second electrode on the photoelectric conversion layer;
a second substrate on the second electrode; and
a sealing member disposed between the first electrode and the second substrate and configured to seal at least the photoelectric conversion layer,
the first electrode including a through section,
the sealing member being in contact with the first substrate through the through section.

2. The photoelectric conversion element according to claim 1,
wherein the through section includes through holes disposed in a dot pattern with even gaps.

3. The photoelectric conversion element according to claim 2,
wherein the through holes satisfy a formula A>B, where A is a minimum opening length of the through hole and B is a minimum distance between the through holes adjacent to each other.

4. The photoelectric conversion element according to claim 3,
wherein the minimum opening length A is 5 μm or greater but 500 μm or less.

5. The photoelectric conversion element according to claim 3,
wherein the minimum distance B is 1 μm or greater but 400 μm or less.

6. The photoelectric conversion element according to claim 1,
wherein an average thickness of the first electrode is 5 nm or greater but 100 μm or less.

7. The photoelectric conversion element according to claim 1, further comprising a hole-blocking layer,
wherein the hole-blocking layer is disposed between the first electrode and the sealing member,
the hole-blocking layer includes a through section connected to the through section of the first electrode, and
the sealing member is in contact with the first substrate through the through section of the hole-blocking layer and the through section of the first electrode.

8. The photoelectric conversion element according to claim 1,
wherein an average thickness of the hole-blocking layer is 5 nm or greater but 1 μm or less.

9. The photoelectric conversion element according to claim 1,
wherein the photoelectric conversion layer includes an electron-transport layer and a hole-transport layer.

10. The photoelectric conversion element according to claim 9,
wherein an average thickness of the electron-transport layer is 100 nm or greater but 100 μm or less.
